(19) United States
(12) Patent Application Publication
(10) Pub. No.: US 2011/0255330 A1
(43) Pub. Date: Oct. 20, 2011

(54) NONVOLATILE SEMICONDUCTOR MEMORY DEVICE

(75) Inventors: Takahiko SASAKI, Tokyo (JP); Tomonori Kurosawa, Zama-shi (JP)

(73) Assignee: Kabushiki Kaisha Toshiba, Tokyo (JP)

(21) Appl. No.: 13/051,614

(22) Filed: Mar. 18, 2011

(30) Foreign Application Priority Data
Mar. 24, 2010 (JP) P2010-67758

(51) Int. Cl. G11C 11/21

(52) U.S. Cl. 365/148

(57) ABSTRACT

A nonvolatile semiconductor memory device according to one embodiment of the present invention includes a memory cell array configured by memory cells each provided between a first line and a second line and each including a variable resistor. A control circuit applies to any one of the memory cells through the first and second lines a voltage necessary for an operation of any one of the memory cells. A current limiting circuit is connected to the first line and limits a current flowing across the memory cell during an operation to a certain limit value. During an operation, the control circuit supplies a first voltage to the first line while supplying to the second line a second voltage. The second voltage lowers over time.

### CROSS REFERENCE TO RELATED APPLICATIONS

This application is based on and claims the benefit of priority from prior Japanese Patent Application No. 2010-67758, filed on Mar. 24, 2010, the entire contents of which are incorporated herein by reference.

### FIELD

Embodiments described herein relate generally to a nonvolatile semiconductor memory device.

### BACKGROUND

In recent years, along with a rising level of integration in semiconductor devices, circuit patterns of transistors and the like which configure the semiconductor devices are being increasingly miniaturized. Required in this miniaturization of the patterns is not simply a thinning of line width but also an improvement in dimensional accuracy and positional accuracy of the patterns. This trend applies also to semiconductor memory devices.

Conventionally known and marketed semiconductor memory devices such as DRAM, SRAM, and flash memory each use a MOSFET as a memory cell. Consequently, there is required, accompanying the miniaturization of patterns, an improvement in dimensional accuracy at a rate exceeding a rate of the miniaturization. As a result, a large burden is placed also on the lithography technology for forming these patterns which is a factor contributing to a rise in product cost.

In recent years, resistance varying memory is attracting attention as a candidate to succeed these kinds of semiconductor memory devices utilizing a MOSFET as a memory cell (refer, for example, to Patent Document 1). For example, there is known a resistance change memory (ReRAM: Resistive RAM) that has a transition metal oxide as a recording layer and is configured to store a resistance state in a nonvolatile manner.

In a so-called unipolar-type element, write of data to a memory cell is implemented by applying for a short time to a variable resistor a certain setting voltage Vset. As a result, the variable resistor changes from a high-resistance state to a low-resistance state. Hereinafter, this operation to change the variable resistor from a high-resistance state to a low-resistance state is called a setting operation.

In contrast, in a so-called unipolar-type element, erase of data in the memory cell MC is implemented by applying for a long time to the variable resistor in the low-resistance state subsequent to the setting operation a resetting voltage Vreset which is lower than the setting voltage Vset of a time of the setting operation. As a result, the variable resistor changes from the low-resistance state to the high-resistance state. Hereinafter, this operation to change the variable resistor from a low-resistance state to a high-resistance state is called a resetting operation. The memory cell, for example, has the high-resistance state as a stable state (a reset state), and, in the case of binary data storage, data write is implemented by the setting operation which changes the reset state to the low-resistance state.

Subsequent to forming a memory cell structure in this kind of resistance change memory, it is necessary to execute a forming operation for applying to the memory cell a forming voltage which is a voltage greater than a writing voltage in order to set the memory cell to a state where it is usable as a memory cell, i.e., a state where it can change between a high-resistance state and a low-resistance state.

If the forming voltage and a current in the forming operation become too high, the resistance of the memory cell after the forming is completed might become too low or in some case the memory cell might be destroyed. Particularly, the current in the forming operation greatly changes from when the forming operation is started, and hence it is necessary to execute control for limiting the upper limit value, etc. Meanwhile, it is also requested to reduce the time taken for the forming operation.

Also in the setting operation or the resetting operation, a cell current greatly changes from when the setting operation or the resetting operation is started, and hence it is necessary to limit the upper limit value of the cell current.

### BRIEF DESCRIPTION OF THE DRAWINGS

FIG. 1 is a block diagram of a nonvolatile semiconductor memory device according to an embodiment of the present invention.

FIG. 2 is a perspective diagram of a portion of a memory cell array 1.

FIG. 3 is a cross-sectional diagram of FIG. 2 taken along a line I-I′ and seen in the direction of arrow, showing one memory cell.

FIG. 4 shows another example of the configuration of the memory cell array 1.

FIG. 5 shows another example of the configuration of the memory cell array 1.

FIG. 6 is a circuit diagram of the memory cell array 1 and its peripheral circuits.

FIG. 7 shows an operation of the nonvolatile semiconductor memory device according to a first embodiment of the present invention during a forming operation.

FIG. 8 shows the configuration of a nonvolatile semiconductor memory device according to a second embodiment of the present invention.

FIG. 9 is a circuit diagram showing an example of a specific configuration of a regulator 11 of FIG. 8.

### DETAILED DESCRIPTION

A nonvolatile semiconductor memory device according to an embodiment includes a memory cell array including memory cells arranged therein, each of the memory cells being provided between a first line and a second line and including a variable resistor. A control circuit is configured to apply to any one of the memory cells through the first and second lines a voltage necessary for an operation of any one of the memory cells. A current limiting circuit is connected to the first line and limits a current flowing across the memory cell during an operation to a certain limit value. During an operation, the control circuit supplies a first voltage to the first line while supplying to the second line a second voltage which lowers over time.

Embodiments of the present invention will be explained in detail with reference to the drawings.

### [Overall Configuration]

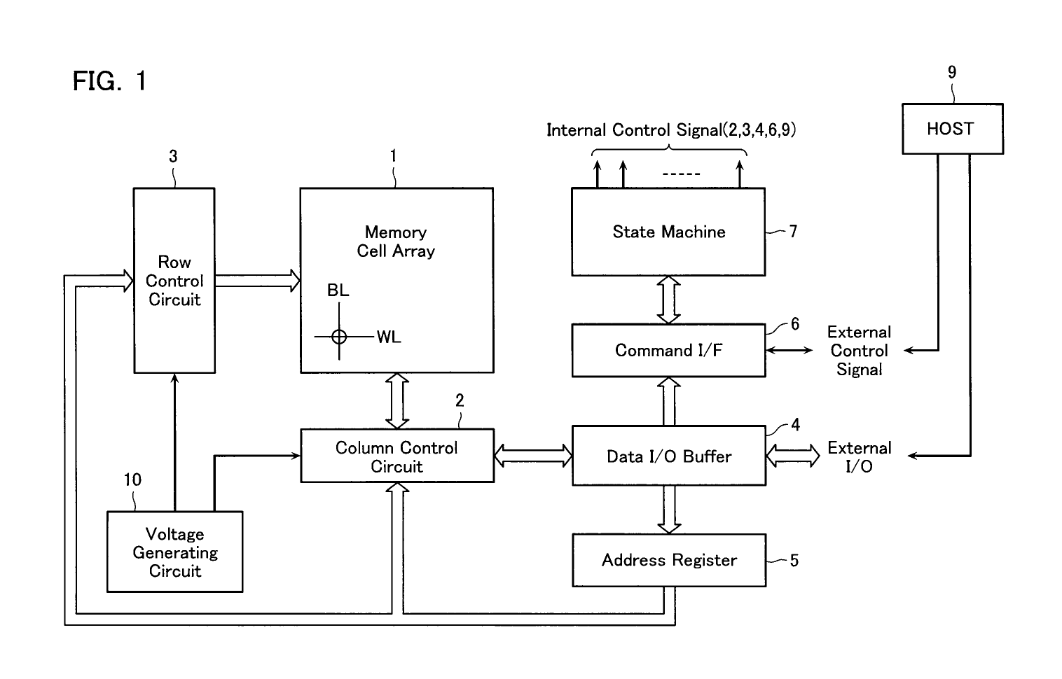

FIG. 1 is a block diagram of a nonvolatile memory according to a first embodiment of the present invention.

The nonvolatile memory includes a memory cell array 1 in which memory cells each using a variable resistor are arranged in a matrix.

Provided at a position adjoining the memory cell array 1 in a bit line BL direction is a column control circuit 2 configured to control the bit lines BL of the memory cell array 1 and execute erasing of data from a memory cell, writing of data to a memory cell, and reading of data from a memory cell.

Provided at a position adjoining the memory cell array 1 in a word line WL direction is a row control circuit 3 configured to select a word line WL of the memory cell array 1 and apply voltages necessary for erasing of data from a memory cell, writing of data to a memory cell, and reading of data from a memory cell.

A data I/O buffer 4 is connected to an external host 9 via an I/O line, and receives write data and an erase instruction, outputs read data, and receives address data and command data. The data I/O buffer 4 sends received write data to the column control circuit 2, and receives read data from the column control circuit 2 to output it to the outside. An address supplied to the data I/O buffer 4 from the outside is sent to the column control circuit 2 and the row control circuit 3 via an address register 5.

A command supplied by the host 9 to the data I/O buffer 4 is sent to a command interface 6. The command interface 6 receives an external control signal from the host 9, determines whether data input in the data I/O buffer 4 is write data, a command, or an address, and when it is a command, transfers it as a received command signal to a state machine 7.

The state machine 7 manages the nonvolatile memory on the whole, receives a command from the host 9 via the command interface 6, and executes management of reading, writing, erasing, data I/O, etc.

The external host 9 can also receive status information managed by the state machine 7 and determine an operation result. The status information is also used for controlling writing and erasing.

A voltage generating circuit 10 is controlled by the state machine 7. Under this control, the voltage generating circuit 10 can output a pulse of an arbitrary voltage at an arbitrary timing.

The generated pulse can be transferred to an arbitrary line selected by the column control circuit 2 and the row control circuit 3. The peripheral circuit elements other than the memory cell array 1 can be formed on a Si substrate immediately under the memory cell array 1 formed in an interconnection layer, and hence the chip area of the nonvolatile memory can be substantially equal to the area of the memory cell array 1.

### [Memory Cell Array and its Peripheral Circuits]

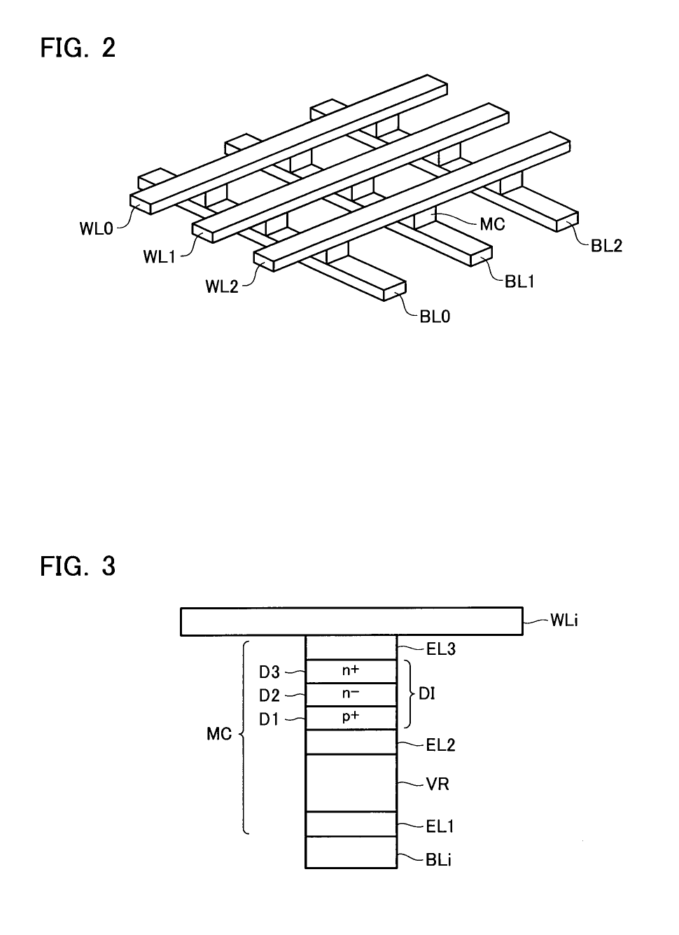

FIG. 2 is a perspective diagram of a portion of the memory cell array 1. FIG. 3 is cross-sectional diagram of FIG. 2 taken along a line I-I′ and seen in the direction of arrow, showing one memory cell. There are provided parallel word lines WL0 to WL2 as a plurality of first lines, parallel bit lines BL0 to BL2 as a plurality of second lines intersecting the word lines, and memory cells MC each provided at the intersection of the word line and bit line to be sandwiched therebetween. It is preferable that the first and second lines be made of a heat-resistant material having a low resistance value, such as W, WSi, NiSi, CoSi, etc.

### [Memory Cell MC]

As shown in FIG. 3, a memory cell MC is configured by a series circuit of a variable resistor VR and a diode DI. The variable resistor VR can be made of, for example, carbon (C). Other than this, it may be made of a material having a resistance value which can change in response to voltage application. As shown in FIG. 3, the diode DI is configured by a PIN diode including a p+ type layer D1, an n− type layer D2, and an n+ type layer D3, and formed sandwiched between electrodes EL2 and EL3. The “+” and “−” signs indicate level difference of impurity concentration.

The electrode material of the electrodes EL1 to EL3 may be Pt, Au, Ag, TiAlN, SrRuO, Ru, RuN, Ir, Co, Ti, TiN, TaN, LaNiO, Al, PtIrOx, PtRhOx, Rh/TaAlN, W, etc. A metal film that provides uniform orientation may be inserted. A buffer layer, a barrier metal layer, an adhesive layer, etc. may also be inserted separately.

### [Modified Example of Memory Cell Array]

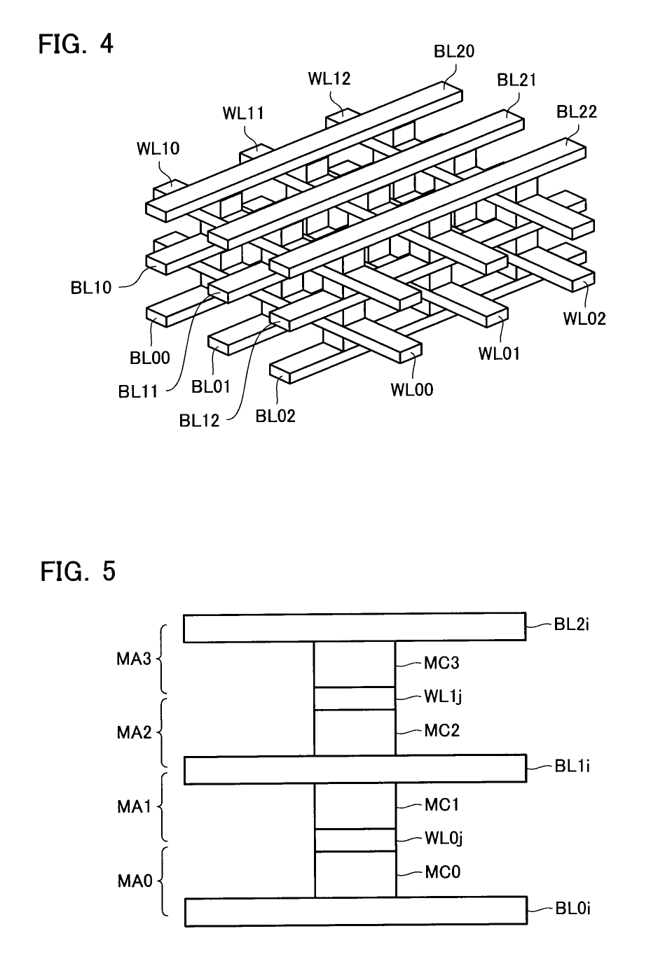

As shown in FIG. 4, a three-dimensional configuration including plural layers of the memory configuration described above is also available. FIG. 5 is a cross-sectional diagram of FIG. 4 taken along a line II-II′. The shown example is a four-layered memory cell array configured by cell array layers MA0 to MA3. A word line WL0j is shared by memory cells MC0 and MC1 above and below the word line WL0j. A bit line BL1i is shared by memory cells MC1 and MC2 above and below the bit line BL1i. A word line WL1j is shared by memory cells MC2 and MC3 above and below the word line WL1j.

The layered configuration needs not be a repetition of line/cell/line/cell described above, but may be a repetition of line/cell/line/interlayer insulating film/line/cell/line with an interlayer insulating film provided between the cell array layers. The memory cell array 1 may also be divided into some memory cell groups MAT. The column control circuit 2 and the row control circuit 3 described above may be provided per MAT, per sector, or per cell array layer MA, or may be shared by them. Alternatively, these circuits may be shared by a plurality of bit lines BL for the purpose of area reduction.

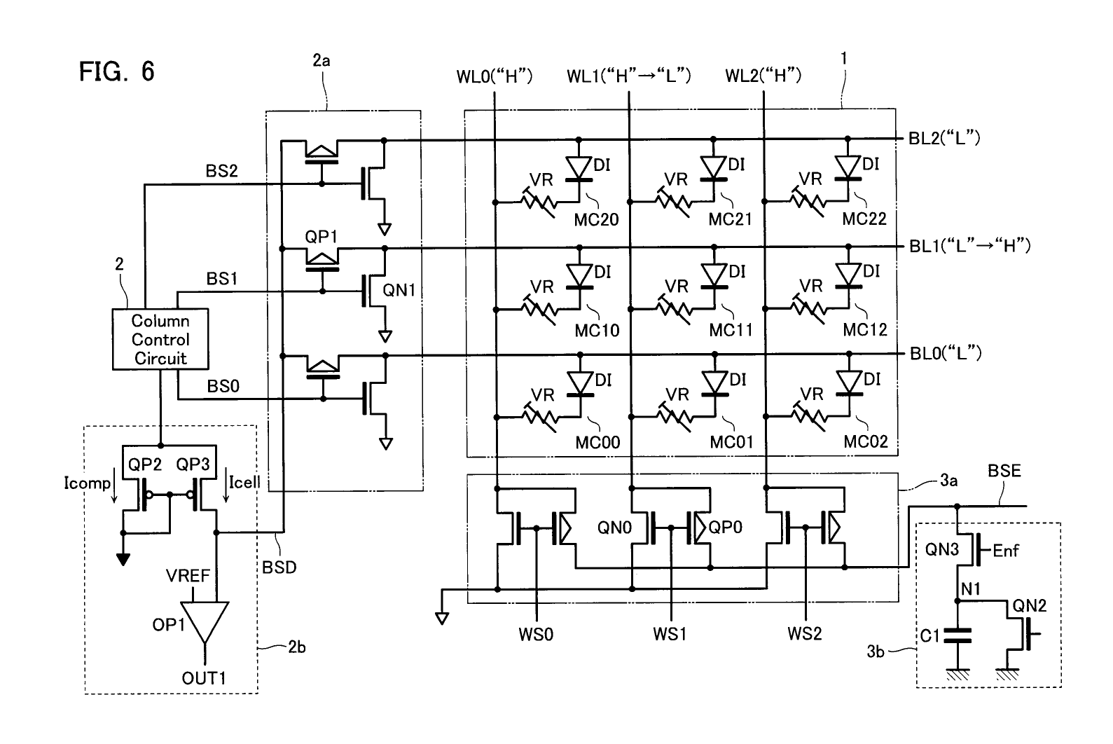

FIG. 6 is a circuit diagram of the memory cell array 1 and its peripheral circuits. In order to simplify the explanation, the following description assumes that the memory cell array 1 is a single-layered configuration. In FIG. 6, the diode DI configuring a memory cell MC has its anode connected to a bit line BL and its cathode connected to a word line WL via the variable resistor VR. One end of each bit line BL is connected to a selecting circuit 2a configuring a part of the column control circuit 2. One end of each word line WL is connected to a selecting circuit 3a configuring a part of the row control circuit 3.

The selecting circuits 2a include a selecting PMOS transistor QP1 and a selecting NMOS transistor QN1 provided for a bit line BL. The PMOS transistor QP1 and selecting NMOS transistor QN1 have their gates and drains connected commonly. The sources of the selecting PMOS transistors QP1 are connected commonly to a drain-side drive line BSD. The source of the selecting NMOS transistor QN1 is connected to a grounding terminal.

The transistor QP1 and the transistor QN1 have their drains connected to a bit line BL, and their gates supplied with a bit line selecting signal BSi for selecting each bit line BL.

The selecting circuits 3a include a selecting PMOS transistor QP0 and a selecting NMOS transistor QN0 provided for a word line WL. The selecting PMOS transistor QP0 and selecting NMOS transistor QN0 have their gates and drains connected commonly. The source of the selecting PMOS transistor QP0 is connected to a word line-side drive line BSE for applying a writing pulse and flowing a current to be detected in a data reading operation. The source of the selecting NMOS transistor QN0 is connected to a grounding terminal (a ground voltage Vss). The transistors QP0 and QN0 have their common drain connected to a word line WL and their common gate supplied with a word line selecting signal WSi for selecting each word line WL.

In the memory cell array 1, the polarity of the diode DI may be reversed from the polarity in the circuit of FIG. 6 (i.e., the diode DI may be connected to have a forward direction from a word line WL to a bit line BL), such that a current may flow from a word line WL side to a bit line BL side.

The column control circuit 2 includes a current limiting circuit 2b shown in FIG. 6. The current limiting circuit 2b is a circuit configured to ensure that a current Icell flowing across a memory cell MC does not exceed an upper limit value Icomp.

For example, the current limiting circuit 2b includes a current mirror circuit configured by PMOS transistors QP2 and QP3. The PMOS transistor QP2 is diode-connected, and has its source connected to the column control circuit 2 to be supplied with a certain constant voltage. The drain of the PMOS transistor QP2 is connected to a grounding terminal.

The source of the PMOS transistor QP3 is also supplied with a certain constant voltage from the column control circuit 2. The gate of the PMOS transistor QP3 is connected to the gate of the PMOS transistor QP2, and the drain thereof is connected to the drain-side drive line BSD. Thereby, the current Icell flowing across the memory cells MC through the bit lines BL and the drain-side drive line BSD is limited to the limit current Icomp or lower.

The current limiting circuit 2b includes an OP amplifier (differential amplifier circuit) OP1. The OP amplifier OP1 has its one input terminal connected to the drain-side drive line BSD, and its other input terminal supplied with a reference voltage VREF from an unillustrated constant voltage generating circuit. When the current Icell flowing through the drain-side drive line BSD has become higher, the OP amplifier OP1 differentially amplifies the voltage of this drain-side drive line BSD and the reference voltage VREF, and outputs a differential amplification signal OUT1. The differential amplification signal OUT 1 is input to the state machine 7 via the command I/F 6. The state machine 7 controls the column control circuit 2 and the voltage generating circuit 10 in accordance with an internal control signal to stop voltage supply to the bit lines BL.

On the other hand, the row control circuit 3 includes, as a part thereof, a voltage control circuit 3b configured to lower over time the voltage to be supplied to the word lines WL. The voltage control circuit 3b includes a capacitor C1, a discharging NMOS transistor QN2, and an enabling NMOS transistor QN3. The capacitor C1 and the transistor QN2 are both connected between a node N1 and a grounding terminal. The transistor QN3 is connected between the node N1 and the word line-side drive line BSE to form a current path therebetween, and becomes conductive in accordance with an enable signal Enf. After the drive line BSE is charged up to a certain voltage by the row control circuit 3 and the transistor QN3 becomes conductive, the capacitor C1 is also charged, raising the voltage across both ends of the capacitor C1 to a certain voltage.

After this, when a forming operation or the like is started and then the transistor QN2 becomes conductive, the capacitor C1 is discharged and the voltage of the drive line BSE gradually lowers. As a result, the voltage of the word lines WL also lowers over time. At this time, it is possible to adjust the lowering speed of the voltage of the word lines WL by controlling the level of the gate signal to the transistor QN2.

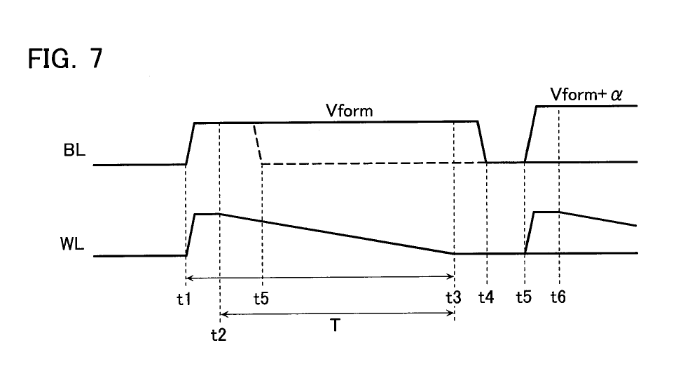

Next, the forming operation of the nonvolatile semiconductor memory device according to the present embodiment will be explained with reference to FIG. 7.

First, at the timing t1, the voltage of the bit lines BL rises to a voltage Vform. At the same time, the voltage of the word lines WL also rises to the voltage Vform. Then, at the timing t2, under the control of the voltage control circuit 3b, the voltage of the word lines WL starts to lower gradually to the ground voltage Vss. The voltage of the word lines WL becomes the ground voltage Vss at the timing t3. If the current limiting circuit 2b detects at a timing between the timings t2 and t3, for example at the timing t5 that the current Icell of the memory cells MC has reached the limit current Icomp, the voltage of the bit lines BL lowers from the voltage Vform to the ground voltage Vss, and hence the forming operation is completed.

If the cell current Icell has not reached the limit current Icomp between the timings t2 and t3, the voltage of the bit lines BL lowers to the ground voltage Vss at the timing t4. In this case, the forming operation is executed again at the timing t5 with adjustments such as raising the voltage Vform by, for example, a voltage value α, setting the limit current Icomp to a larger value, etc. Thereafter, the forming operation is repeated until the cell current Icell reaches the limit current Icomp. It is preferable that the time T between the timings t2 and t3 be set to about a hundred times as large as a normal slew rate of the word lines WL, for example, to about 200 mS.

In this way, according to the present embodiment, in the forming operation, a voltage is applied to the memory cell under a condition that the voltage of the bit lines BL is maintained to a constant value while the voltage of the word lines WL is caused to lower over time. Because the voltage applied to the memory cell changes continuously, there is no need of changing the limit current Icomp frequently. As a result, it becomes possible to reduce the forming time.

The bit lines BL are provided with the current limiting circuit 2b configured to detect whether the cell current Icell has exceeded the limit current Icomp or not, and the current limiting circuit 2b includes the current mirror circuit. In order for the current mirror circuit to operate properly, it is necessary to maintain the voltage of the bit lines BL to a constant value during the forming operation. For this reason, according to the present embodiment, in the forming operation, the voltage of the word lines WL is caused to lower over time instead of the voltage of the bit lines BL being caused to rise over time. According to this scheme, it is possible to detect correctly whether the cell current Icell has exceeded the limit current Icomp or not, even while changing the voltage applied for the forming operation to the memory cell continuously. Consequently, it is possible to reduce the time taken for the forming operation even while preventing destruction of the memory cells.

Though the operation of each circuit has been explained as regards the forming operation as an example, also in the setting operation or the resetting operation, it is possible to prevent destruction of the memory cells and reduce the time taken for the operation by making each circuit operate in the same way as described above.

### Second Embodiment

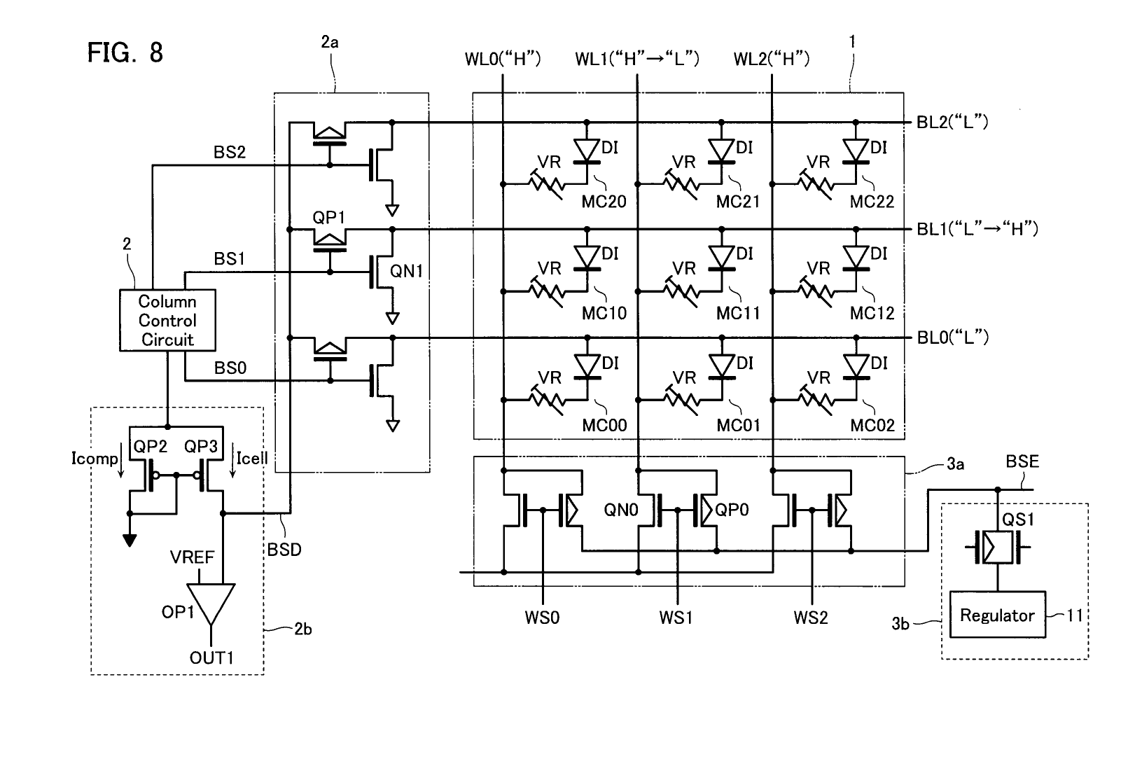

Next, a nonvolatile semiconductor memory device according to a second embodiment of the present invention will be explained with reference to FIG. 8. The present embodiment is different from the first embodiment in the configuration of the voltage control circuit 3b. The present embodiment is the same as the first embodiment in the other respects, and the same components as in the first embodiment are denoted by the same reference numerals in FIG. 8 and will not be explained in detail below.

The voltage control circuit 3b of the present embodiment includes a regulator 11 and a switch circuit QS1. The regulator 11 has a function of actively driving the drive line BSE that is charged to a given voltage, to a certain voltage when the switch circuit QS1 becomes on.

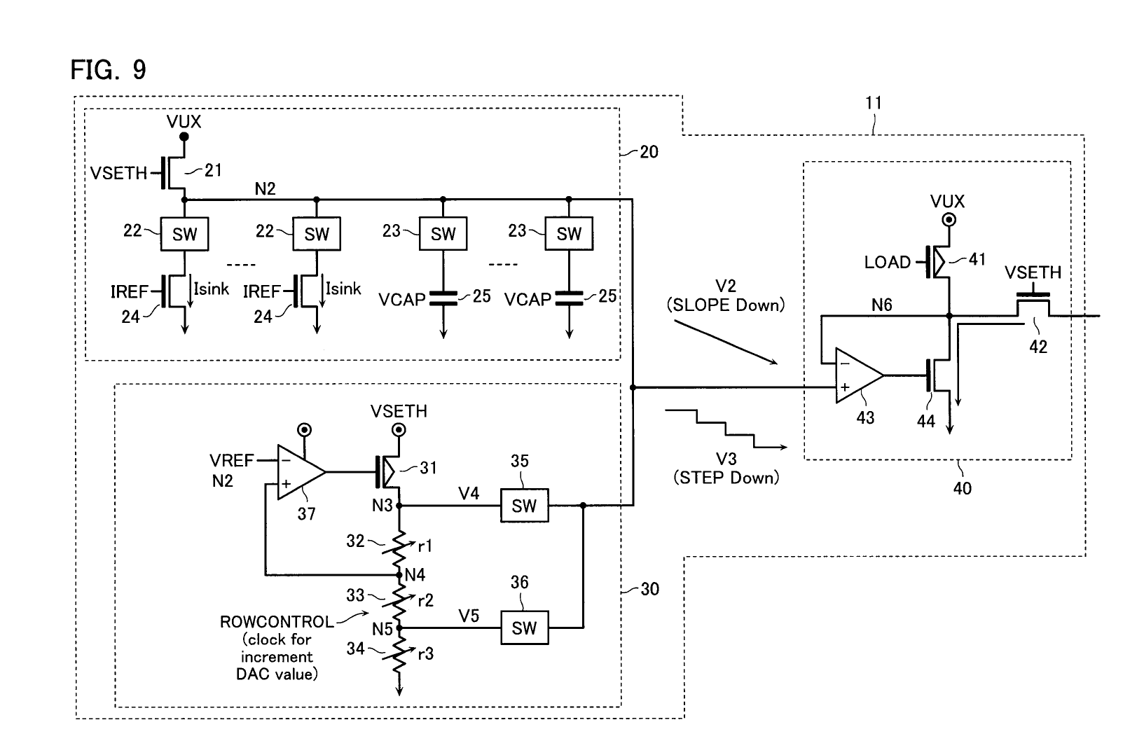

FIG. 9 shows an example of a specific configuration of the regulator 11 in the voltage control circuit 3b. The regulator 11 includes voltage generating circuits 20 and 30 and a discharge control circuit 40. The voltage generating circuit 20 supplies a voltage V2 which lowers over time continuously in a forming operation, a setting operation, or a resetting operation. On the other hand, the voltage generating circuit 30 supplies a voltage V3 which lowers over time stepwise in a forming operation, a setting operation, or a resetting operation. Either the voltage generating circuit 20 or 30 is selectively brought to an operated state in accordance with a control signal from the state machine 7.

The voltage generating circuit 20 includes an NMOS transistor 21, a plurality of switching circuits 22, a plurality of switching circuits 23, a plurality of NMOS transistors 24, and a plurality of capacitors 25.

The NMOS transistor 21 has its drain supplied with a voltage VUX (about 5V) and its source connected to a node N2. For example, the voltage VUX may be set to the same voltage as a voltage supplied to unselected word lines WL, but is not limited to such a voltage. The NMOS transistor 21 becomes conductive when the gate thereof is supplied with a gate signal VSETH (=VUX+Vth (Vth: threshold voltage of the NMOS transistor 21)), and hence charges the node N2 to the voltage VUX.

The switching circuits 22 and 23 are each connected between the node N2 and an NMOS transistor N24 and between the node N2 and a capacitor 25. The other end of each NMOS transistor 24 and the other end of each capacitor 25 are grounded.

The capacitance of the capacitors 25 changes depending on how many of the plurality of switching circuits 23 to switch on, which enables to change the lowering speed of the voltage V2.

After the node N2 is charged, some or all of the plurality of switching circuits 22 is/are switched on and a gate signal IREF becomes “H” making the transistors 24 conductive, which causes the voltage of the node N2 to lower from the voltage VUX to a ground voltage VSS. At this time, by changing the number of switching circuits 22 to switch on, it is possible to change the lowering speed of the voltage V2.

The voltage generating circuit 30 includes a PMOS transistor 31, variable resistors 32 to 34 configuring a divided resistance circuit, switching circuits 35 and 36, and an OP amplifier (differential amplifier circuit) 37. The PMOS transistor 31 has its source supplied with the voltage VSETH and its drain connected to one end of the resistor 32. The variable resistors 32 to 34 are connected in series, and the other end of the variable resistor 34 is grounded. The switching circuit 35 has its one end connected to a node N3 at which the PMOS transistor 31 and the variable resistor 32 are connected, and the other end connected to the node N2. The switching circuit 36 has its one end connected to a node N5 at which the variable resistors 33 and 34 are connected, and the other end connected to the node N2.

The OP amplifier 37 has its inverting input terminal supplied with a reference voltage VREF from an unillustrated constant voltage generating circuit and its non-inverting input terminal supplied with the voltage of a node N4 between the variable resistors 32 and 33. The OP amplifier 37 differentially amplifies these two voltages and supplies a resulting differential amplification signal to the gate of the PMOS transistor 31.

The variable resistors 32 to 34 change their resistance values r1, r2, and r3 at a timing of a clock signal supplied by an unillustrated clock generating circuit in accordance with a control signal supplied by the state machine 7. The resistance values r1 to r3 are changed in a manner that the voltages V4 and V5 of the nodes N3 and N5 lower the voltage levels stepwise. The voltage V4 or V5 is supplied as the voltage V3 to the node N2 by the switching circuits 35 and 36 being switched therebetween.

The discharge control circuit 40 includes a PMOS transistor 41, a selecting NMOS transistor 42, an OP amplifier (differential amplifier circuit) 43, and an NMOS transistor 44.

The PMOS transistor 41 has its source supplied with the voltage VUX and its drain connected to a node N6. The PMOS transistor 41 becomes conductive when the gate there of is supplied with a control signal LOAD, and hence charges the node N6 to the voltage VUX. The NMOS transistor 42 is connected between the word lines WL and the node N6 to form a current path therebetween, and timely becomes conductive when a voltage VSETH is supplied to its gate.

The OP amplifier 43 has its inverting input terminal connected to the node N6 and its non-inverting input terminal connected to the node N2. A differential amplification signal output by the OP amplifier 43 is supplied to the gate of the NMOS transistor 44. The NMOS transistor 44 forms a current path between the node N6 and a grounding terminal.

When the voltage V2 or V3 has lowered over time, the OP amplifier 43 raises the voltage level of the differential amplification signal to output from its output terminal, thereby controlling the source-drain current of the transistor 44. When the voltage V2 or V3 lowers, a discharge current from the word lines WL becomes higher and the lowering speed of the voltage of the word lines WL becomes higher. According to the second embodiment, it is possible to control the lowering speed of the voltage of the word lines WL and control the voltage of the word lines WL more accurately than according to the first embodiment, by making various adjustments by means of the voltage generating circuit 20 or 30.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a memory cell array including memory cells arranged therein, each of the memory cells being provided between a first line and a second line and including a variable resistor;
a control circuit configured to apply to any one of the memory cells through the first and second lines a voltage necessary for an operation of any one of the memory cells; and
a current limiting circuit connected to the first line and configured to limit a current flowing across the memory cell during the operation to a certain limit value,
the control circuit being configured to supply a first voltage to the first line while supplying to the second line a second voltage, the second voltage lowering over time.

2. The nonvolatile semiconductor memory device according to claim 1,
wherein when the current limiting circuit detects that a current flowing across the memory cells has reached the limit value, the control circuit stops supplying the first voltage.

3. The nonvolatile semiconductor memory device according to claim 2,
wherein the control circuit includes:
a capacitor having one end connected to the second line and the other end connected to a grounding terminal; and
a switch circuit having one end connected to the second line and the other end connected to a grounding terminal, and configured to discharge the voltage of the second line at a certain timing.

4. The nonvolatile semiconductor memory device according to claim 2,
wherein the control circuit includes:
a voltage generating circuit configured to supply a third voltage which lowers over time;
a differential amplifier circuit configured to differentially amplify the third voltage and a voltage of the second lines and output a differential amplification signal; and
a transistor forming a current path between the second line and a grounding terminal and configured to control a current flowing through the current path in accordance with the differential amplification signal input to a control terminal thereof.

5. The nonvolatile semiconductor memory device according to claim 4,
wherein the voltage generating circuit includes:
a first voltage generating circuit configured to lower a voltage value of the third voltage continuously over time; and
a second voltage generating circuit configured to lower the voltage value of the third voltage stepwise over time.

6. The nonvolatile semiconductor memory device according to claim 1,
wherein the control circuit includes:
a capacitor having one end connected to the second line and the other end connected to a grounding terminal; and
a switch circuit having one end connected to the second line and the other end connected to a grounding terminal, and configured to discharge the voltage of the second line at a certain timing.

7. The nonvolatile semiconductor memory device according to claim 1,
wherein the control circuit includes:
a voltage generating circuit configured to supply a third voltage which lowers over time;
a differential amplifier circuit configured to differentially amplify the third voltage and a voltage of the second line and output a differential amplification signal; and
a transistor forming a current path between the second line and a grounding terminal, and configured to control a current flowing through the current path in accordance with the differential amplification signal input to a control terminal thereof.

8. The nonvolatile semiconductor memory device according to claim 7,
wherein the voltage generating circuit includes:
a first voltage generating circuit configured to lower a voltage value of the third voltage continuously over time; and
a second voltage generating circuit configured to lower the voltage value of the third voltage stepwise over time.

9. The nonvolatile semiconductor memory device according to claim 1,
wherein when the current limiting circuit detects that a current flowing across the memory cell has reached the limit value, the control circuit switches a voltage supplied to the first line from the first voltage to a fourth voltage.

10. The nonvolatile semiconductor memory device according to claim 9,
wherein the control circuit includes:
a capacitor having one end connected to the second line and the other end connected to a grounding terminal; and
a switch circuit having one end connected to the second line and the other end connected to a grounding terminal, and configured to discharge the voltage of the second line at a certain timing.

11. The nonvolatile semiconductor memory device according to claim 9,
wherein the control circuit includes:
a voltage generating circuit configured to supply a third voltage which lowers over time;
a differential amplifier circuit configured to differentially amplify the third voltage and a voltage of the second line and output a differential amplification signal; and
a transistor forming a current path between the second line and a grounding terminal, and configured to control a current flowing through the current path in accordance with the differential amplification signal input to a control terminal thereof.

12. The nonvolatile semiconductor memory device according to claim 1,
wherein the control circuit is configured to execute an operation of supplying the first voltage to the first line while supplying to the second line the second voltage, the second voltage lowering over time, when executing a forming operation for making the memory cell capable of changing between a high-resistance state and a low-resistance state.

13. The nonvolatile semiconductor memory device according to claim 1,
wherein when the current limiting circuit detects that a current flowing across the memory cell has reached the limit value, the control circuit stops supplying the first voltage,
whereas when the current limiting circuit detects that the current flowing across the memory cell has not reached the limit value within a certain period, the control circuit stops supplying the first voltage, and after this, switches the first voltage from a first value to a second value to again supply the first voltage to the first line while supplying to the second line the second voltage which lowers over time.

14. The nonvolatile semiconductor memory device according to claim 13,
wherein the control circuit includes:
a capacitor having one end connected to the second line and the other end connected to a grounding terminal; and
a switch circuit having one end connected to the second line and the other end connected to a grounding terminal, and configured to discharge the voltage of the second line at a certain timing.

15. The nonvolatile semiconductor memory device according to claim 13,
wherein the control circuit includes:
a voltage generating circuit configured to supply a third voltage which lowers over time;
a differential amplifier circuit configured to differentially amplify the third voltage and a voltage of the second line and output a differential amplification signal; and
a transistor forming a current path between the second line and a grounding terminal, and configured to control a current flowing through the current path in accordance with the differential amplification signal input to a control terminal thereof.

16. The nonvolatile semiconductor memory device according to claim 15,
wherein the voltage generating circuit includes:
a first voltage generating circuit configured to lower a voltage value of the third voltage continuously over time; and
a second voltage generating circuit configured to lower the voltage value of the third voltage stepwise over time.

17. The nonvolatile semiconductor memory device according to claim 13,
wherein the control circuit is configured to execute an operation of supplying the first voltage to the first line while supplying to the second line the second voltage which lowers over time, when executing a forming operation for making the memory cell capable of changing between a high-resistance state and a low-resistance state.

18. A method of controlling a nonvolatile semiconductor memory device including a memory cell array configured by memory cells each provided between a first line and a second line and each including a variable resistor, the method comprising:
when executing a certain operation, supplying a first voltage to the first line while supplying to the second line a second voltage which lowers over time; and
limiting a current flowing across the memory cells connected to the first line to a certain limit value.

19. The method of controlling the nonvolatile semiconductor memory device according to claim 18,
wherein when it is detected that a current flowing across the memory cell has reached the limit value, supplying of the first voltage is stopped.

20. The method of controlling the nonvolatile semiconductor memory device according to claim 19,
wherein when it is detected that the current flowing across the memory cell has not reached the limit value within a certain period, supplying of the first voltage is stopped, and after this, the first voltage is switched from a first value to a second value to be again supplied to the first line, while the second voltage which lowers over time is supplied to the second line.
